(19) United States
(12) Patent Application Publication
(10) Pub. No.: US 2025/0215293 A1
(43) Pub. Date: Jul. 3, 2025

(54) ADHESIVE COMPOSITION

(71) Applicant: SHIN-ETSU POLYMER CO., LTD., Chiyoda-ku, Tokyo (JP)

(72) Inventors: Shiori MOMMA, Saitama (JP); Kazuyoshi YOSHIDA, Saitama (JP); Wataru KATAGIRI, Saitama (JP)

(21) Appl. No.: 18/851,684

(22) PCT Filed: Nov. 2, 2022
(86) PCT No.: PCT/JP2022/041028

§ 371 Date: Sep. 27, 2024

(30) Foreign Application Priority Data
Mar. 30, 2022 (JP) 2022-054776

(51) Int. Cl. C09J 179/08; C09J 7/30

(52) U.S. Cl. CPC C09J 179/08; C09J 7/30; C09J 2463/00; C09J 2479/08

(57) ABSTRACT

The present invention provides a resin composition for forming a low-dielectric adhesive layer that has 5G compatible good electrical properties (low-dielectric properties), ensures high adhesiveness, and also has a small linear thermal expansion coefficient (CTE), and an adhesive composition containing the resin composition. The adhesive composition contains a maleimide resin (A) having a molecular weight of 1,000 or more, a benzoxazine resin (B), and an alkenyl resin (C) having a 1-alkenyl group, and a mixing ratio between the benzoxazine resin (B) and the alkenyl resin (C) in the resin composition is 1:10 to 10:1.

### TECHNICAL FIELD

The present invention relates to an adhesive composition. More specifically, the present invention relates to an adhesive composition that can be used for adhesive applications of electronic parts and the like.

### BACKGROUND ART

As electronic devices become more compact and lightweight, bonding applications of electronic parts and the like are diversifying, and the demand for laminated bodies provided with an adhesive layer is increasing.

Further, for flexible printed circuit boards (hereinafter, also referred to as FPCs), which are one type of electronic part, there is a need to process large amounts of data at high speed, and so support for high frequencies is progressing. To increase the frequency of FPCs, it is necessary to reduce the dielectric of the components, and low-dielectric base films and low-dielectric adhesives are being developed. In particular, for efficiently transmitting signals having frequencies in the 6 GHz and 28 GHz bands used in the 5th Generation Mobile Communication System (hereinafter also referred to as the 5G), a base film and an adhesive having a small loss in the millimeter wavelength band of 28 GHz have become more and more significant.

However, low-dielectric adhesives have low molecular polarity, and hence it is difficult to exhibit adhesiveness with the base film and other components related to electronic parts. Low-dielectric base films also similarly have poor adhesiveness with adhesives in some cases, and hence there is a need for improvement in the adhesiveness.

In order to achieve high heat resistance and adhesiveness (which is referred to as “adhesion property” in Patent Literature 1), a thermosetting resin composition containing a maleimide resin (which is referred to as a “maleimide compound” in Patent Literature 1), an allyl group-containing phenol resin, and an oxazine resin (which is referred to as a “benzoxazine compound” in Patent Literature 1) has been proposed (see, for example, Patent Literature 1).

### CITATION LIST

### Patent Literature

Patent Literature 1: Japanese Patent Laid-Open No. 2019-99755

### SUMMARY OF INVENTION

### Technical Problem

When an adhesive is produced referring to the resin composition described in Patent Literature 1 described above, however, the molecular weight of the maleimide resin is so low that adhesiveness is not obtained, and therefore, the adhesive is not sufficient from the viewpoint of ensuring high adhesiveness, and needs to be improved.

For improving the adhesiveness, the present inventors produced a resin composition with a maleimide resin having a high molecular weight, but when the maleimide resin having a high molecular weight was used, although the adhesiveness was higher, a linear thermal expansion coefficient (CTE) of an adhesive layer formed using the resin composition was large. When the CTE is large, warpage is caused in a laminated body obtained therefrom, and hence the processability is degraded to degrade dimensional stability and adhesiveness of a resultant film, and therefore, there is a demand for a resin composition capable of forming an adhesive layer having a small CTE value.

Therefore, an object of the present invention is to provide a resin composition for forming a low-dielectric adhesive layer that has 5G compatible good electrical properties (low-dielectric properties), ensures high adhesiveness, and also has a small linear thermal expansion coefficient (CTE), and an adhesive composition containing the resin composition.

### Solution to Problem

As a result of diligent research to solve the above-described problems, the present inventors have found that a resin composition containing, in a high molecular weight maleimide resin, a benzoxazine resin and an alkenyl resin having a 1-alkenyl group in a specific ratio can solve the above-described problems, and thus, the present invention has been accomplished.

The present invention encompasses the following aspects:

[1] An adhesive composition containing a resin composition containing a maleimide resin (A) having a molecular weight of 1,000 or more, a benzoxazine resin (B), and an alkenyl resin (C) having a 1-alkenyl group, wherein a mixing ratio between the benzoxazine resin (B) and the alkenyl resin (C) in the resin composition is 1:10 to 10:1.
[2] The adhesive composition according to [1], wherein the number of carbon atoms in the 1-alkenyl group is 5 or less.
[3] The adhesive composition according to [2], wherein the 1-alkenyl group is a 1-propenyl group.
[4] The adhesive composition according to any one of [1] to [3], wherein the benzoxazine resin (B) has a molecular weight of 1,000 or less.
[5] The adhesive composition according to any one of [1] to [4], wherein the benzoxazine resin (B) has a softening point of 100° C. or less.
[6] The adhesive composition according to any one of [1] to [5], wherein the alkenyl resin (C) has a molecular weight of 1,000 or less.
[7] The adhesive composition according to any one of [1] to [6], wherein the alkenyl resin (C) has a softening point of 100° C. or less.
[8] The adhesive composition according to any one of [1] to [7], wherein, as a mixing ratio among the maleimide resin (A), the benzoxazine resin (B), and the alkenyl resin (C), 62.5 to 99.8 parts by mass of the maleimide resin (A), 0.1 to 25 parts by mass of the benzoxazine resin (B), and 0.1 to 12.5 parts by mass of the alkenyl resin (C) are mixed based on 100 parts by mass of the resin composition.
[9] The adhesive composition according to any one of [1] to [8], wherein the mixing ratio between the benzoxazine resin (B) and the alkenyl resin (C) is 1:3 to 3:1.
[10] The adhesive composition according to any one of [1] to [9], wherein when the resin composition contains an epoxy resin, a content of the epoxy resin is less than 5 parts by mass based on 100 parts by mass of the resin composition.
[11] The adhesive composition according to [10], wherein when the resin composition contains the epoxy resin, the content of the epoxy resin is less than 3 parts by mass based on 100 parts by mass of the resin composition.
[12] The adhesive composition according to any one of [1] to [9], wherein the resin composition contains no epoxy resin.
[13] The adhesive composition according to any one of [1] to [12], further comprising a filler in addition to the resin composition.
[14] An adhesive layer obtained by curing the adhesive composition according to [13].
[15] The adhesive layer according to [14], wherein the adhesive layer has relative permittivity measured at 28 GHz of 3.5 or less, and a dielectric loss tangent of 0.005 or less.
[16]A laminate comprising:
a base film; and
the adhesive layer according to [14] or [15].
   [17] The laminate according to [16], wherein the base film contains a polyether ether ketone (PEEK) resin.
   [18]A coverlay film provided with an adhesive layer, comprising the laminate according to [16] or [17].
   [19]A copper-clad laminate comprising the laminate according to [16] or [17].
   [20]A printed circuit board comprising the laminate according to [16] or [17].
   [21]A shield film comprising the laminate according to [16] or [17].
   [22]A printed circuit board provided with a shield film, comprising the laminate according to [16] or [17].

### Advantageous Effects of Invention

According to the present invention, a resin composition for forming a low-dielectric adhesive layer that has 5G compatible good electrical properties (low-dielectric properties), ensures high adhesiveness, and also has a small linear thermal expansion coefficient (CTE), and an adhesive composition containing the resin composition can be provided.

### DESCRIPTION OF EMBODIMENTS

Hereinafter, the adhesive composition of the present invention, the laminate including an adhesive layer composed of the adhesive composition, and electronic-parts-related components including the laminate will be described in detail, but the following description of the constituent requirements is one example of an embodiment of the present invention, and the present invention is not limited to the subject matters described here.

### (Adhesive Composition)

The adhesive composition of the present invention contains a resin composition.

The resin composition contains a maleimide resin (A) having a molecular weight of 1,000 or more, a benzoxazine resin (B), and an alkenyl resin (C) having a 1-alkenyl group.

In the resin composition, a mixing ratio between the benzoxazine resin (B) and the alkenyl resin (C) is 1:10 to 10:1.

The resin composition may contain another resin component, if necessary, in addition to a resin component of the maleimide resin (A) having a molecular weight of 1,000 or more, a resin component of the benzoxazine resin (B), and the alkenyl resin having a 1-alkenyl group.

The adhesive composition of the present invention may contain, in addition to the above-described resin composition contained as the resin components, another component such as a filler, a curing accelerator, and various additives.

Herein, a “resin composition” contains a resin component, and does not contain another component such as a filler (particularly, an inorganic filler), a curing accelerator, and various additives.

Since the adhesive composition contains the maleimide resin having a high molecular weight, the oxazine resin and the alkenyl resin having a specific structure, a low-dielectric adhesive layer having good electrical properties (low-dielectric properties), high adhesiveness, and a small CTE can be formed.

### <Maleimide Resin (A)>

The resin composition of the present invention contains a maleimide resin having a molecular weight of 1,000 or more.

The maleimide resin refers to a resin having a maleimide group, and in the present invention, the maleimide resin is more preferably a bismaleimide resin having two maleimide groups.

The maleimide resin has good adhesiveness with a metal, has an unsaturated bond, and is capable of crosslinking, and the adhesive composition of the present invention containing the maleimide resin has a high crosslink density, and is excellent in heat resistance, solvent resistance and the like.

The maleimide resin has an imide skeleton, and hence imparts high adhesiveness with a metal to the adhesive composition, and thus it is difficult for an acid or a base to enter between a cured product of the adhesive composition and the metal, and as a result, chemical resistance can be improved.

The maleimide resin reacts with the benzoxazine resin or the alkenyl resin to form a crosslinked structure. Through the reaction with the benzoxazine resin or the alkenyl resin, the crosslink density of the adhesive composition is increased, and thus, high adhesiveness with an adherend, heat resistance of a cured product of the adhesive, and a small linear thermal expansion coefficient (CTE) can be exhibited.

Examples of the maleimide resin include a modified maleimide obtained by modifying a maleimide resin with a compound having primary amine, and a polymer or the like obtained by chain elongation of a maleimide resin with an amine modified product, such as a dimer acid or a trimer acid, and maleic anhydride or pyromellitic acid.

As the maleimide resin, a commercially available compound may be used, and specifically, for example, a rewin with the trade name “SLK-3000-T50” or “SLK-2600-A50” manufactured by Shin-Etsu Chemical Co., Ltd. or the like may be suitably used.

In the present invention, the maleimide resin is used preferably as a main resin of the resin composition.

Accordingly, from the viewpoints of reducing the linear thermal expansion coefficient and improving the adhesiveness, the content of the maleimide resin is preferably larger than 50 parts by mass based on 100 parts by mass of the resin composition. More specifically, the lower limit of the content of the maleimide resin in the resin composition is, from the viewpoint that further lower dielectric properties can be obtained, preferably 62.5 parts by mass or more, and from the viewpoint that the adhesiveness can be further increased, preferably 77.5 parts by mass or more. On the other hand, the upper limit of the content of the maleimide resin in the resin composition is more preferably 99.8 parts by mass or less, and further preferably 99 parts by mass or less.

As the maleimide resin, a mixture of a plurality of different maleimide resins may be used. When a mixture of a plurality of maleimide resins is used, the content is a total amount of the plurality of maleimide resins.

The melting point or the softening point of the maleimide resin is preferably 30° C. or more, and preferably 130° C. or less from the viewpoints of imparting fluidity to the adhesive composition at a temperature of heat laminating or heat pressing, causing the resin to sufficiently follow the surface of a base film or a metal base, and exhibiting excellent adhesiveness and chemical resistance when cured.

The maleimide resin used in the present invention has a weight average molecular weight of 1,000 or more, preferably 3,000 or more, and more preferably 5,000 or more. When the weight average molecular weight is 3,000 or more, appropriate flexibility can be imparted to a cured product of the adhesive composition. When the weight average molecular weight is 5,000 or more, excellent adhesiveness can be exhibited. The weight average molecular weight of the maleimide resin is preferably 40,000 or less, more preferably 20,000 or less, and further preferably 15,000 or less. When the weight average molecular weight is 40,000 or less, an imide skeleton capable of exhibiting sufficient adhesiveness with a metal can be contained. When the weight average molecular weight is 15,000 or less, compatibility with the benzoxazine resin is improved.

### <Benzoxazine Resin (B)>

The benzoxazine resin reacts with the maleimide resin to increase the crosslink density of the adhesive composition, and thus, high adhesiveness with an adherend can be exhibited. The benzoxazine resin reacts with the maleimide resin and the alkenyl resin to form a crosslinked structure, and thus, a small linear thermal expansion coefficient can be exhibited.

Examples of the benzoxazine resin include 6,6-(1-methylethylidene)bis(3,4-dihydro-3-phenyl-2H-1,3-benzoxazine), and 6,6-(1-methylethylidene)bis(3,4-dihydro-3-methyl-2H-1,3-benzoxazine), and two or more of these may be used in combination. To nitrogen of the oxazine ring, a phenyl group, a methyl group, a cyclohexyl group, or the like may be bonded. Specific examples of the benzoxazine resin include “Benzoxazine F-a”, “Benzoxazine P-d”, and “Benzoxazine ALP-d” manufactured by Shikoku Chemicals Corporation, and “CR-276” and “BZ-LB-MDA” manufactured by TOHOKU CHEMICAL INDUSTRIES, LTD.

The benzoxazine resin of the present invention may be a benzoxazine resin having a portion represented by the following formula (1):

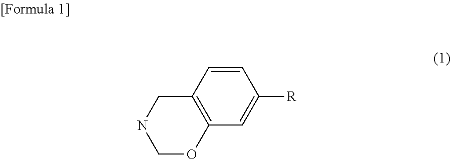

In the formula (1), R represents a hydrocarbon group having 4 or more carbon atoms. The hydrocarbon group may have an unsaturated bond portion.

In the formula (1), the number of carbon atoms of R is more preferably 12 or more, further preferably 14 or more, and particularly preferably 15 or more. The number of carbon atoms of R is preferably 20 or less in consideration of the compatibility of the oxazine resin in the resin composition.

R in the formula (1) preferably has a straight chain structure. Thus, excellent flexibility of the adhesive layer can be ensured.

Besides, the hydrocarbon group of R in the formula (1) preferably has at least one or more unsaturated bond portions. Thus, a good thermosetting reaction can be ensured.

R in the formula (1) is preferably any one of groups represented by the following formulas (i) to (iv):

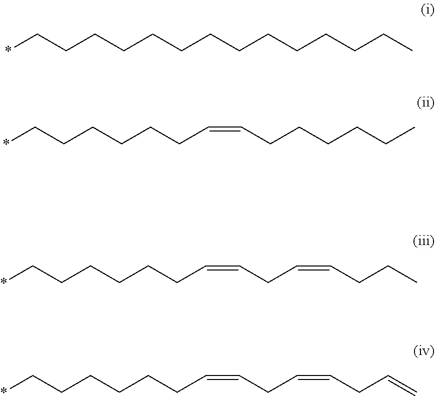 [SMILES: *CCCCCCCCCCCCCC ; *CCCCCC/C=C\CCCCCC ; *CCCCCC/C=C\C/C=C\CCC ; *CCCCCC/C=C\C/C=C\CC=C]

In the formulas (i) to (iv), * represents a bonding hand.

Besides, the benzoxazine resin of the present invention is not limited to a benzoxazine resin in which R is one type substituent but may be a plurality of benzoxazine resins containing different types of R in the formula (1), namely, a mixture of two or more benzoxazine resins.

For example, when the benzoxazine resin has the portion of R represented by the formulas (i) to (iv) descried above, the benzoxazine resin is not limited to one in which R is represented by any one of the formulas (i) to (iv), but the benzoxazine resin may be a mixture of a plurality of benzoxazine resins containing different Rs selected from those of the formulas (i) to (iv).

More specifically, the benzoxazine resin may contain at least two or more benzoxazine resins selected from the group consisting of, for example, the following:
a benzoxazine resin represented by the formula (1) in which R is a group represented by the formula (i);
a benzoxazine resin represented by the formula (1) in which R is a group represented by the formula (ii);
a benzoxazine resin represented by the formula (1) in which R is a group represented by the formula (iii); and
a benzoxazine resin represented by the formula (1) in which R is a group represented by the formula (iv).

The benzoxazine resin preferably has a structure containing two or more oxazine skeletons in a molecule. Thus, with the content of the maleimide resin having high adhesiveness increased, the crosslink density can be improved.

An example of the benzoxazine resin includes a benzoxazine resin represented by the following formula (2):

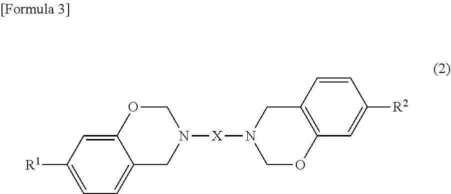

In the formula (2), R¹ and R² are respectively defined the same as R in the formula (1). X represents a divalent organic group. Examples include an alkylene group having 1 to 5 carbon atoms, and a group represented by the following formula (3):

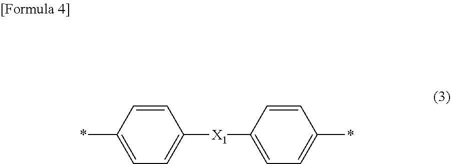

In the formula (3), X1 represents an alkylene group having 1 to 5 carbon atoms, and * represents a bonding hand.

In the formula (2), R¹ and R² more preferably represent any one of the alkyl groups represented by the formulas (i) to (iv) described above.

The content of the benzoxazine resin is, from the viewpoint of good reactivity, preferably 0.1 parts by mass or more, and more preferably 1 part by mass or more based on 100 parts by mass of the resin composition. The content of the benzoxazine resin is preferably 25 parts by mass or less from the viewpoint that the adhesiveness is increased with the linear thermal expansion coefficient reduced for attaining low-dielectric properties, and is more preferably 15 prats by mass or less from the viewpoint that the adhesiveness can be further increased.

When the content of the benzoxazine resin falls in the above-described range, the low-dielectric properties and good adhesiveness of the adhesive layer formed with the adhesive composition containing the resin composition can be ensured.

As the benzoxazine resin, a mixture of a plurality of different benzoxazine resins may be used. When a mixture of a plurality of benzoxazine resins is used, the content is a total amount of the plurality of benzoxazine resins.

The melting point or the softening point of the benzoxazine resin is preferably 100° C. or less from the viewpoints of imparting fluidity to the adhesive composition at a temperature of heat laminating or heat pressing, causing the resin to sufficiently follow the surface of a base film or a metal base, and exhibiting excellent adhesiveness.

The melting point or the softening point of the benzoxazine resin is preferably 40° C. or more from the viewpoint that the elastic modulus at room temperature of the adhesive composition can be improved to improve adhesion.

The benzoxazine resin used in the present invention has a weight average molecular weight of preferably 1,000 or less. When the weight average molecular weight is 1,000 or less, the compatibility among the respective components in the resin composition can be ensured.

### <Alkenyl Resin (C)>

The alkenyl resin reacts with the maleimide resin to increase the crosslink density of the adhesive composition, and thus, high adhesiveness with an adherend can be exhibited. The alkenyl resin reacts with the maleimide resin and the oxazine resin to form a crosslinked structure, and thus, a small linear thermal expansion coefficient can be exhibited.

An alkenyl resin exhibits high reactivity when it has a 1-alkenyl group.

From the viewpoint of reduction of steric hindrance, the number of carbon atoms in the 1-alkenyl group is preferably 5 or less.

A preferable structure of the 1-alkenyl group can be a 1-vinyl group, a 1-propenyl group, an isopropenyl group, a 1-butenyl group, and a 1-pentenyl group.

Among these, a 1-propenyl group is more preferred from the viewpoint that the linear thermal expansion coefficient can be further reduced.

In the present invention, the alkenyl resin is particularly preferably an aromatic alkenyl resin (aromatic propenyl resin) having a structure represented by the following formula (4):

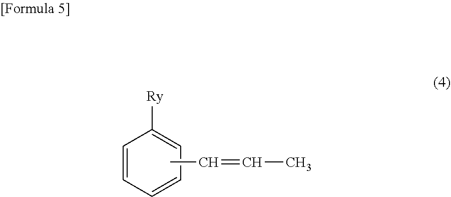

In the formula (4), Ry represents H, a hydrocarbon group having 1 to 11 carbon atoms, a hydroxy group, or a cyanate group.

The content of the alkenyl resin is preferably more than 0 parts by mass based on 100 parts by mass of the resin composition from the viewpoint that the reactivity is improved, and more preferably 0.1 parts by mass or more, and further preferably 1 part by mass or more from the viewpoint that the reactivity is further improved. The content of the alkenyl resin is preferably 25 parts by mass or less from the viewpoint of increasing the adhesiveness with the linear thermal expansion coefficient reduced, is more preferably 12.5 parts by mass or less from the viewpoint that further low-dielectric properties can be obtained, and is further preferably 7.5 parts by mass or less from the viewpoint that the adhesiveness can be further increased.

When the content of the alkenyl resin falls in the above-described range, the low-dielectric properties and the small linear thermal expansion coefficient of the adhesive layer formed with the adhesive composition can be favorably ensured.

As the alkenyl resin, a mixture of a plurality of different alkenyl resins may be used. When a mixture of a plurality of alkenyl resins is used, the content is a total amount of the plurality of alkenyl resins.

The melting point or the softening point of the alkenyl resin is preferably 100° C. or less from the viewpoints of imparting fluidity to the adhesive composition at a temperature of heat laminating or heat pressing, causing the resin to sufficiently follow the surface of a base film or a metal base, and exhibiting excellent adhesiveness.

The melting point or the softening point of the alkenyl resin is preferably 40° C. or more from the viewpoint that the elastic modulus at room temperature can be improved to improve adhesion.

The alkenyl resin used in the present invention has a weight average molecular weight of preferably 1,000 or less. When the weight average molecular weight is 1,000 or less, good compatibility among the respective components in the resin composition can be ensured.

In the resin composition, the mixing ratio between the benzoxazine resin (B) and the alkenyl resin (C) is 1:10 to 10:1 in terms of a mass ratio. When these resins are contained in this specific content ratio in the resin composition, the reaction temperature is lowered than in a case where each of the benzoxazine resin (B) and the alkenyl resin (C) is singly blended, and thus, curing can be further promoted. Besides, when the mass ratio is 1:3 to 3:1, damage on a base can be inhibited, and from the viewpoint of energy, the crosslink density can be increased even through after-curing at 150° C. causing smaller environmental load, and therefore, the low-dielectric properties and the small linear thermal expansion coefficient of the adhesive layer can be favorably ensured.

As a mixing ratio among the maleimide resin (A), the benzoxazine resin (B), and the alkenyl resin (C), for example, based on 100 parts by mass of the resin composition, it is preferable to contain 62.5 to 99.8 parts by mass of the maleimide resin (A), 0.1 to 25 parts by mass of the benzoxazine resin (B), and 0.1 to 12.5 parts by mass of the alkenyl resin (C) based on 100 parts by mass of the resin composition.

The resin composition of the present invention may contain, in addition to the maleimide resin, the benzoxazine resin, and the alkenyl resin, another resin component as long as the effects of the present invention are not impaired.

### <Other Resin Components>

The resin composition of the present invention may contain another thermosetting resin in addition to the maleimide resin, the benzoxazine resin, and the alkenyl resin. Alternatively, the resin composition of the present invention may contain a styrene-based elastomer, or another thermoplastic resin.

Examples of another thermosetting resin include an epoxy resin, a phenol resin, an unsaturated imide resin (excluding the maleimide resin), a cyanate resin, an isocyanate resin, an oxetane resin, an amino resin, an unsaturated polyester resin, an allyl resin, a dicyclopentadiene resin, a silicone resin, a triazine resin, and a melamine resin. Although an epoxy resin is superior among these from the viewpoints of moldability and electric insulation, adhesiveness can be exhibited by blending the maleimide resin, the oxazine resin, and the alkenyl resin, and hence, from the viewpoint of dielectric properties, it is preferable that an epoxy resin is minimally contained. Accordingly, when the resin composition contains an epoxy resin, the content of the epoxy resin is preferably less than 5 parts by mass based on 100 parts by mass of the resin composition from the viewpoint of the low-dielectric properties, and more preferably less than 3 parts by mass from the viewpoint of increasing the adhesiveness, and it is further preferable that the epoxy resin is not contained from the viewpoint of attaining further low-dielectric properties.

The styrene-based elastomer refers to a copolymer mainly containing a block or random structure of unsaturated hydrocarbon and an aromatic vinyl compound, or a hydrogenated product thereof.

Examples of the aromatic vinyl compound include styrene, t-butylstyrene, α-methylstyrene, divinylbenzene, 1,1-diphenylethylene, N,N-diethyl-p-aminoethylstyrene and vinyltoluene.

Examples of the unsaturated hydrocarbon include ethylene, propylene, butadiene, isoprene, isobutene, 1,3-pentadiene, and 2,3-dimethyl-1,3-butadiene.

Examples of another thermoplastic resin include a phenoxy resin, a polyamide resin, a polyester resin, a polycarbonate resin, a polyphenylene oxide resin, a polyurethane resin, a polyacetal resin, a polyethylene resin, a polypropylene resin, a polybutadiene resin, and a polyvinyl resin. One of these thermoplastic resin may be singly used, or two or more of these may be used together.

### <Other Components>

The adhesive composition of the present invention may contain other components such as a filler, a curing accelerator, and various additives in addition to the resin composition containing the maleimide resin, the benzoxazine resin, the alkenyl resin, and the other resin components and the like described above.

Examples of other components include a filler, a curing accelerator, a flame retardant, a heat aging inhibitor, a leveling agent, an antifoaming agent, and a pigment. These components may be contained as long as the function of the adhesive composition is not affected.

### <<Filler>>

The adhesive composition of the present invention preferably contains a filler.

As the filler of the present invention, an inorganic filler is preferred, for example, from the viewpoints of heat resistance, and control of mechanical properties of the adhesive composition.

Examples of the inorganic filler include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, silicon carbonate, a quartz powder, short glass fiber, a fine glass powder, and hollow glass. Among these, silica, mica, talc, a quarts powder, short glass fiber, a fine glass powder, and hollow glass are preferred from the viewpoints of dielectric properties, heat resistance, low thermal expansion, and the like, and silica is more preferred from the viewpoint that a thin film can be formed.

Examples of silica include precipitated silica having a high water content and produced by a wet method, and fumed silica minimally containing bound water and produced by a dry method.

The inorganic filler may be surface treated with a coupling agent.

As the filler of the present invention, an organic filler may be contained, for example, from the viewpoints of dispersibility and brittleness.

As the organic filler, a styrene-based true spherical filler is preferred, and a styrene-based hollow filler is more preferred from the viewpoint of electrical properties.

One of these may be singly used, or two or more of these may be used in combination.

The content of the filler contained in the adhesive composition of the present invention is preferably 50 to 1,000 parts by mass based on 100 parts by mass of the resin composition from the viewpoint that a small linear thermal expansion coefficient can be exhibited, and is more preferably 80 to 500 parts by mass based on 100 parts by mass of the resin composition from the viewpoint that low-dielectric properties and adhesiveness can be exhibited. From the viewpoint that the adhesiveness can be increased, the content is further preferably 150 to 350 parts by mass based on 100 parts by mass of the resin composition.

The shape of the filler is not especially limited, and can be appropriately selected according to the intended purpose. For example, the inorganic filler may be a spherical inorganic filler, or a non-spherical inorganic filler, and from the viewpoints of the linear thermal expansion coefficient (CTE), and film strength, a non-spherical inorganic filler is preferred. The shape of the non-spherical inorganic filler may be any three-dimensional shape excluding a spherical (substantially spherical) shape, and examples include a plate shape, a scale shape, a rod shape, a chain shape, and a fiber shape. Among these, from the viewpoint of the linear thermal expansion coefficient (CTE), and the film strength, an inorganic filler in a plate shape or a scale shape is preferred, and an inorganic filler in a plate shape is more preferred.

The flame retardant can be either an organic flame retardant or an inorganic flame retardant. Examples of organic flame retardants include: phosphorus-based flame retardants, including melamine phosphate, melamine polyphosphate, guanidine phosphate, guanidine polyphosphate, ammonium phosphate, ammonium polyphosphate, ammonium phosphate amide, ammonium polyphosphate amide, carbamoyl phosphate, carbamoyl polyphosphate, aluminum trisdiethylphosphinate, aluminum trismethylethylphosphinate, aluminum trisdiphenylphosphinate, zinc bisdiethylphosphinate, zinc bismethylethylphosphinate, zinc bisdiphenylphosphinate, titanyl bisdiethylphosphinate, titanium tetrakisdiethylphosphinate, titanyl bismethylethylphosphinate, titanium tetrakismethylethylphosphinate, titanyl bisdiphenylphosphinate and titanium tetrakisdiphenylphosphinate; nitrogen-based flame retardants, including triazine compounds like melamine, melam and melamine cyanurate, cyanuric acid compounds, isocyanuric acid compounds, triazole compounds, tetrazole compounds, diazo compounds and urea; and silicon-based flame retardants, including silicone compounds and silane compounds. Examples of inorganic flame retardants include metal hydroxides, including aluminum hydroxide, magnesium hydroxide, zirconium hydroxide, barium hydroxide and calcium hydroxide; metal oxides, including tin oxide, aluminum oxide, magnesium oxide, zirconium oxide, zinc oxide, molybdenum oxide and nickel oxide; and zinc carbonate, magnesium carbonate, barium carbonate, zinc borate and hydrated glass. These flame retardants can be used in combinations of two or more.

Examples of the heat aging inhibitor include phenol-based antioxidants, including 2,6-di-tert-butyl-4-methylphenol, n-octadecyl-3-(3′,5′-di-tert-butyl-4′-hydroxyphenyl)propionate, tetrakis[methylene-3-(3,5-di-tert-butyl-4-hydroxyphenyl)propionate]methane, pentaerythritol tetrakis[3-(3,5-di-t-butyl-4-hydroxyphenol and triethylene glycol-bis[3-(3-t-butyl-5-methyl-4-hydroxyphenyl)propionate; sulfur-based antioxidants, including dilauryl-3,3′-thiodipropionate and dimyristyl-3,3′-dithiopropionate; and phosphorus-based antioxidants, including trisnonylphenylphosphite and tris(2,4-di-tert-butylphenyl)phosphite. These can be used singly or in combinations of two or more.

### (Adhesive Layer)

An adhesive layer of the present invention is formed using the adhesive composition of the present invention described above.

The adhesive composition that forms the adhesive layer can be cured.

The curing method is not particularly limited, and can be appropriately selected according to the intended purpose. Examples of the curing method include heat curing.

The thickness of the adhesive layer is not especially limited, but can be appropriately selected according to the intended purpose, and is, for example, preferably 3 μm or more, and more preferably 5 μm or more. The thickness is preferably 100 μm or less, more preferably 50 μm or less, and further preferably 30 μm or less. When the thickness of the adhesive layer is 3 μm or more, sufficient adhesion can be exhibited, and when the thickness is 5 μm or more, the adhesive layer can be formed to follow a level difference of a pattern and the like of a printed wiring board. When the thickness of the adhesive layer is 50 μm or less, a laminate formed therefrom can be thinned, and when the thickness is 30 μm or less, a resin flow can be accurately controlled.

### <Method for Producing Adhesive Layer>

The adhesive layer can be produced by forming a film of the adhesive composition.

The adhesive composition can be produced by mixing the maleimide resin, the benzoxazine resin, and the alkenyl resin described above. A mixing method is not especially limited as long as the resultant adhesive composition is homogeneous. Since the adhesive composition is used preferably in the form of a solution or a dispersion, a solvent is usually used.

Examples of the solvent include alcohols, including methanol, ethanol, isopropyl alcohol, n-propyl alcohol, isobutyl alcohol, n-butyl alcohol, benzyl alcohol, ethylene glycol monomethyl ether, propylene glycol monomethyl ether, diethylene glycol monomethyl ether, and diacetone alcohol; ketones, including acetone, methyl ethyl ketone, methyl isobutyl ketone, methyl amyl ketone, cyclohexanone, and isophorone; aromatic hydrocarbons, including toluene, xylene, ethylbenzene, mesitylene, and anisole; esters, including methyl acetate, ethyl acetate, butyl acetate, ethylene glycol monomethyl ether acetate, and 3-methoxybutyl acetate; and aliphatic hydrocarbons, including hexane, heptane, cyclohexane, and methylcyclohexane. One of these solvents may be used singly, or two or more of these may be used in combination. In particular, when a small amount of cyclohexane is added to toluene capable of dissolving a resin having a low polarity, the compatibility with a curing agent and the like is improved, and thus the adhesive layer can be homogenous.

When the adhesive composition is a solution or a dispersion (resin varnish) including a solvent, the application to the base film and the formation of the adhesive layer can be smoothly carried out to readily obtain an adhesive layer having a desired thickness.

When the adhesive composition includes a solvent, the solid concentration is preferably in the range of 3 to 80% by mass, and more preferably 10 to 50% by mass, from the viewpoint of workability including formation of the adhesive layer. If the solid concentration is 80% by mass or less, a solution with a suitable viscosity can be obtained to facilitate uniform coating.

As a more specific embodiment of the method for producing the adhesive layer, a B-stage adhesive layer can be formed by coating a surface of a base film with a resin varnish containing the above-mentioned adhesive composition and a solvent to form a resin varnish layer, and then removing the solvent from the resin varnish layer. As used herein, adhesive layer in B-stage refers to a semi-cured state in which the adhesive composition is uncured or part of the adhesive composition has started to cure, so that the curing of the adhesive composition further proceeds by heating or the like.

Here, the method of applying the resin varnish on the base film is not particularly limited, and can be appropriately selected according to the intended purpose. Examples of the method include a spray method, a spin coating method, a dip method, a roll coating method, a blade coating method, a doctor roll method, a doctor blade method, a curtain coating method, a slit coating method, a screen printing method, an inkjet method and a dispensing method.

The B-stage adhesive layer can be further heated, for example to form a cured adhesive layer.

### <Properties of Adhesive Layer>

The adhesive layer obtained by curing the adhesive composition of the present invention preferably has a relative permittivity (Er) at a frequency of 28 GHz of preferably 3.5 or less, and more preferably 2.7 or less. A dielectric loss tangent (tan δ) at a frequency of 28 GHz of the adhesive layer is preferably 0.005 or less, more preferably 0.0025 or less, and further preferably 0.0015 or less.

When the relative permittivity is 3.5 or less, and the dielectric loss tangent is 0.005 or less, the adhesive layer can be used even in components of high-frequency FPC-related products with strict requirements for electrical properties. Besides, when the relative permittivity is 2.7 or less, and the dielectric loss tangent is 0.0025 or less, electrical properties expected in components of 5G compatible high-frequency FPC-related products can be satisfied, electrical properties equivalent to those of LCP can be obtained, and hence, the adhesive layer can be suitably used in components of 5G compatible high-frequency FPC-related products with strict requirements for electrical properties. Besides, when the dielectric loss tangent is 0.0015 or less, the adhesive layer can be suitably used in high-frequence FPC-related products utilizing millimeter waves.

### [Relative Permittivity and Dielectric Loss Tangent]

The relative permittivity and dielectric loss tangent of the adhesive layer can be measured using a network analyzer MS46122B (manufactured by Anritsu Corporation) and an open resonator Fabry-Perot DPS-03 (manufactured by KEYCOM Corporation) by an open resonator method under the conditions of a temperature of 23° C. and a frequency of 28 GHz.

The upper limit of the linear thermal expansion coefficient (CTE) (CTE at 20° C. to 140° C.) of the adhesive layer obtained by curing the adhesive composition of the present invention is preferably less than 500 ppm/K from the viewpoint that warpage of the resultant laminate can be inhibited, and is more preferably less than 200 ppm/K from the viewpoint of ensuring the dimensional stability and adhesiveness of the resultant film. The linear thermal expansion coefficient is further preferably less than 100 ppm/K from the viewpoint that an LCP or MPI, that is, a low-dielectric base film often used, can be suitably used together. The lower limit of the linear thermal expansion coefficient (CTE) (CTE at 20° C. to 140° C.) of the adhesive layer is preferably 10 ppm/K or more, and more preferably 20 ppm/K or more.

The linear thermal expansion coefficient (CTE) can be measured in accordance with JIS K 7197:1991 with a thermomechanical analyzer (TMA). For example, the measurement is performed in a tensile mode with a thermomechanical analyzer (trade name: SII//SS7100, manufactured by Hitachi High-Tech Science Corporation) under conditions of a load of 50 mN and a temperature increase rate of 5° C./min in a range of 10° C. to 200° C., and a linear thermal expansion coefficient (ppm/K) is obtained based on the inclination in a range of 20° C. to 140° C.

### (Laminate)

The laminate of the present invention includes a base film and the above-mentioned adhesive layer on at least one surface of the base film.

### <Base Film>

The base film used in the present invention can be selected according to the laminate application. For example, when the laminate is to be used as a coverlay film or a copper-clad laminate (CCL), examples of the base film include a polyimide film, a polyether ether ketone film, a polyphenylene sulfide film, an aramid film, a polyethylene naphthalate film, a liquid crystal polymer film, a polyphenylene ether film, and a syndiotactic polystyrene film. Among these, a polyimide film, a polyether ether ketone (PEEK) film, a polyethylene naphthalate film and a liquid crystal polymer film are preferable from the viewpoint of adhesiveness and electrical properties.

The base film can contain a filler. The type of the filler is not especially limited, and can be appropriately selected according to the intended purpose, and for example, the above-described fillers can be used.

Further, when the laminate of the present invention is to be used as a bonding sheet, the base film needs to be a release film, and examples thereof include a polyethylene terephthalate film, a polyethylene film, a polypropylene film, silicone-treated release paper, polyolefin resin-coated paper, a TPX (polymethylpentene) film and a fluororesin film.

When the laminate of the present invention is to be used as a shield film, the base film needs to be a film having an electromagnetic wave shielding ability, and examples thereof include a laminate of a protective insulating layer and a metal foil.

### (Coverlay Film)

An example of a preferable embodiment of the laminate according to the present invention is a coverlay film.

For example, when producing an FPC, a laminate having an adhesive layer called a “coverlay film” is usually used to protect the wiring portion. This coverlay film includes an insulating resin layer and an adhesive layer formed on the surface thereof.

The coverlay film is a laminate in which the above-mentioned adhesive layer is formed on at least one surface of the above-mentioned base film, and it is generally difficult to separate the base film and the adhesive layer.

The thickness of the base film included in the coverlay film is preferably 5 to 100 μm, more preferably 5 to 50 μm, and further preferably 5 to 30 μm. When the thickness of the base film is equal to or less than this upper limit, a thinner coverlay film can be made. If the thickness of the base film is equal to or more than this lower limit, the printed circuit board can be designed easily and handling is also good.

The coverlay film can be produced by, for example, coating a surface of the above-mentioned base film with a resin varnish containing the above-mentioned adhesive composition and a solvent to form a resin varnish layer, and then removing the solvent from the resin varnish layer to produce a coverlay film in which a B-stage adhesive layer is formed.

The drying temperature when removing the solvent is preferably 40 to 250° C., and more preferably 70 to 170° C.

The drying is carried out by passing the laminate having the adhesive composition applied thereon through a furnace in which hot air drying, far infrared heating, high-frequency induction heating or the like is carried out.

Further, optionally, a release film can be laminated onto the surface of the adhesive layer for storage and the like. Examples of the usable release film include those known in the art, including a polyethylene terephthalate film, a polyethylene film, a polypropylene film, silicone-treated release paper, polyolefin resin-coated paper, a TPX film and a fluororesin film.

Since the coverlay film according to the present invention uses the low-dielectric adhesive composition of the present invention, high-speed transmission by electronic devices is possible, and adhesive stability with electronic devices is also excellent.

### (Bonding Sheet)

An example of a preferable embodiment of the laminate according to the present invention is a bonding sheet.

The bonding sheet includes the above-mentioned adhesive layer formed on the surface of a release film (base film). In another embodiment of the bonding sheet, the adhesive layer can be incorporated between two release films. The release film is peeled off when the bonding sheet is used. The same release films as those described above in the section (Coverlay film) can be used.

The thickness of the base film included in the bonding sheet is preferably 5 to 100 μm, more preferably 25 to 75 μm, and further preferably 38 to 50 μm. When the thickness of the base film is within this range, the bonding sheet can be easily produced and handling is also good.

Examples of the method for producing the bonding sheet include a method in which the surface of a release film is coated with a resin varnish containing the above-mentioned adhesive composition and a solvent, and drying is performed in the same manner as in the case of the coverlay film.

Since the bonding sheet according to the present invention uses the low-dielectric adhesive composition of the present invention, high-speed transmission by electronic devices is possible, and adhesive stability with electronic devices is also excellent.

### (Copper-Clad Laminate (CCL))

An example of a preferable embodiment of the laminate according to the present invention is a copper-clad laminate in which a copper foil is bonded to an adhesive layer in the laminate of the present invention.

The copper-clad laminate, which is formed by bonding a copper foil onto the above-mentioned laminate, is composed of, for example, a base film, an adhesive layer and a copper foil, in that order. The adhesive layer and the copper foil can be formed on both sides of the base film.

The adhesive composition used in the present invention also has excellent adhesiveness with articles including copper.

Since the copper-clad laminate according to the present invention uses the low-dielectric adhesive composition of the present invention, high-speed transmission by electronic devices is possible and the adhesive stability is excellent.

Examples of the method for producing the copper-clad laminate include a method in which the adhesive layer of the above-mentioned laminate and a copper foil are brought into surface contact, heat laminating is performed at 80° C. to 200° C., and then the adhesive layer is cured by after-curing. The after-curing conditions can be, for example, 100° C. to 200° C. for 30 minutes to 4 hours in an inert gas atmosphere. The copper foil is not particularly limited, and an electrolytic copper foil, a rolled copper foil and the like can be used.

### (Printed Circuit Board)

An example of a preferable embodiment of the laminate according to the present invention is a printed circuit board in which copper wiring is bonded to an adhesive layer in the laminate of the present invention.

The printed circuit board is obtained by forming an electronic circuit on the above-mentioned copper-clad laminate.

The printed circuit board, which is formed by using the above-mentioned laminate and bonding a base film and copper wiring, is composed of a base film, an adhesive layer and copper wiring, in that order. The adhesive layer and the copper wiring can be formed on both sides of the base film.

The printed circuit board is produced by, for example, sticking a coverlay film onto the surface having the wiring portion with the adhesive layer arranged between the coverlay film and the surface by heat pressing or the like.

Since the printed circuit board according to the present invention uses the low-dielectric adhesive composition of the present invention, high-speed transmission by electronic devices is possible and the adhesive stability is excellent.

Examples of the method for producing the printed circuit board according to the present invention include a method in which the adhesive layer of the above-mentioned laminate and copper wiring are brought into contact, heat laminating is performed at 80° C. to 200° C., and then the adhesive layer is cured by after-curing. The after-curing conditions can be, for example, 100° C. to 200° C. for 30 minutes to 4 hours. The after-curing condition is preferably 150° C. or less because damage on the base can be inhibited, and from the viewpoint that the environmental load is smaller in view of energy. The shape of the copper wiring is not particularly limited, and an appropriate shape and the like can be selected as desired.

### (Shield Film)

An example of a preferable embodiment of the laminate according to the present invention a shield film.

The shield film is a film for shielding various electronic devices in order to cut electromagnetic noise that can affect and cause various electronic devices, including computers, mobile phones, analytical devices and the like, to malfunction. Another name for a shield film is electromagnetic wave shield film.

The electromagnetic wave shield film is formed by, for example, laminating an insulating resin layer, a metal layer, and the adhesive layer of the present invention, in the stated order.

Since the shield film according to the present invention uses the low-dielectric adhesive composition of the present invention, high-speed transmission by electronic devices is possible, and adhesive stability with electronic devices is also excellent.

(Printed Circuit Board Provided with a Shield Film)

An example of a preferable embodiment of the laminate according to the present invention is a printed circuit board provided with a shield film.

A printed circuit board provided with a shield film is formed by sticking the above-mentioned electromagnetic wave shield film on a printed circuit board having a printed circuit provided on at least one side of the substrate.

The printed circuit board provided with a shield film has, for example, a printed circuit board, an insulating film adjacent to the surface of the printed circuit board on the side where the printed circuit is provided, and the above-mentioned electromagnetic wave shield film.

Since the printed circuit board provided with a shield film according to the present invention uses the low-dielectric adhesive composition of the present invention, high-speed transmission by electronic devices is possible and the adhesive stability is excellent.

### EXAMPLES

The present invention will now be described in more detail with reference to the following Examples, but the scope of the present invention is not limited to these Examples. In the following, unless otherwise specified, parts and % are based on mass.

### (Bismaleimide Resin)

A bismaleimide resin with the trade name “SLK-3000-T50” manufactured by Shin-Etsu Chemical Co., Ltd. was used. It had a softening point of 40° C., and a weight average molecular weight of 12,545.

### (Bismaleimide Resin)

A bismaleimide resin with the trade name “SLK-6895-M90” manufactured by Shin-Etsu Chemical Co., Ltd. was used. It had a softening point of 60° C., and a weight average molecular weight of 980.

### (Benzoxazine Resin)

A benzoxazine resin with the trade name “ALP-d” (liquid) manufactured by Shikoku Chemicals Corporation was used.

### (Benzoxazine Resin)

A benzoxazine resin with the trade name “CR-276” manufactured by TOHOKU CHEMICAL INDUSTRIES, LTD. was used. The “CR-276” is a benzoxazine resin having a structure represented by the following formula (1-1), wherein R¹ and R² may be different, and are represented by any one of the following formulas (i) to (iv):

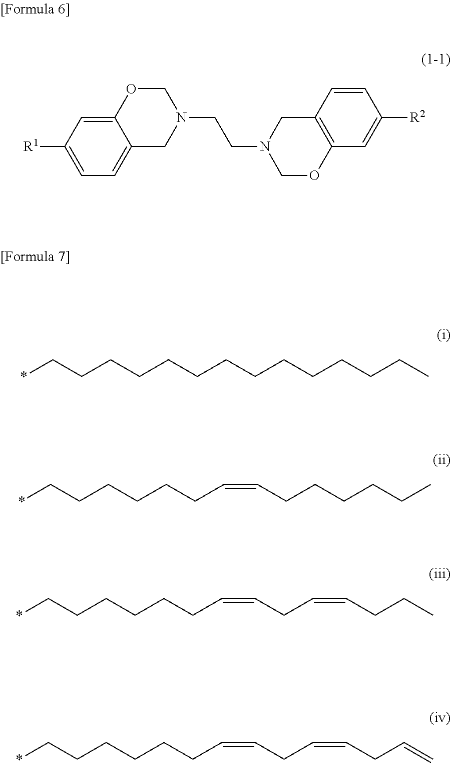

In the formulas (i) to (iv), * represents a bonding hand.

The benzoxazine resin of “CR-276” is in a liquid form at room temperature.

### (Alkenyl Resin)

An alkenyl resin with the trade name “BPN01S” manufactured by Gun Ei Chemical Industry Co., Ltd. was used. The “BPN01S” has a structure of the following formula (5):

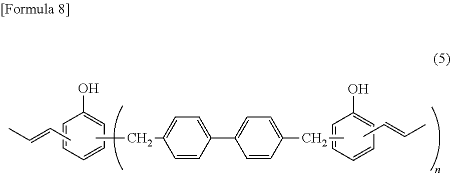

### (Allyl Resin)

An allyl resin with the trade name “APG-LC” manufactured by Gun Ei Chemical Industry Co., Ltd. was used. The “APG-LC” has a structure of the following formula (6):

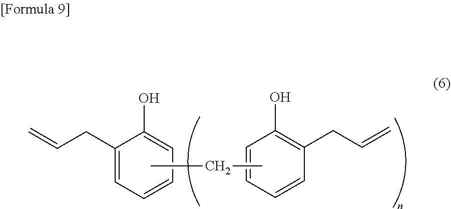

### (Epoxy Resin)

An epoxy resin with the trade name “HP-7200H” manufactured by DIC Corporation was used. solid content: 100%

### (Inorganic Filler (Silica))

An inorganic filler with the trade name “SO—C2” manufactured by Admatechs Company Limited was used. It had a particle size of 0.4 to 0.6 μm, and a specific surface area of 4 to 7 m²/g.

### (Solvent)

A mixed solvent containing toluene and cyclohexanone (in a mass ratio of 97:3) was used.

### (Base Film)

“Shin-Etsu Sepla Film PEEK” (polyether ether ketone, thickness: 50 μm) manufactured by Shin-Etsu Polymer Co., Ltd. was used as the base film. The base film had a storage modulus at 200° C. of 5×10⁸.

### (Electrolytic Copper Foil)

As the electrolytic copper foil, “TQ-M7-VSP” (electrolytic copper foil, thickness of 12 μm, glossy surface Rz of 1.27 μm, glossy surface Ra of 0.197 μm, glossy surface Rsm of 12.95 μm) manufactured by Mitsui Mining & Smelting Co., Ltd. was used.

### (Release Film)

As the release film, NP75SA (silicone release PET film, 75 μm) manufactured by Panac Co., Ltd. was used.

### Example 1

A resin varnish was produced as an adhesive composition containing respective components shown in Table 1 constituting the adhesive layer in the ratio shown in Table 1, and having a solid content concentration of 50% by mass by dissolving these components in a solvent.

Respective components contained in a resin composition in the adhesive composition are shown in Table 1.

The relative permittivity and dielectric loss tangent at a frequency of 28 GHz of the adhesive layer obtained by curing the resin varnish of Example 1 were measured.

### [Relative Permittivity and Dielectric Loss Tangent]

The relative permittivity and dielectric loss tangent of the adhesive layer were measured using a network analyzer MS46122B (manufactured by Anritsu Corporation) and an open resonator Fabry-Perot DPS-03 (manufactured by KEYCOM Corporation) by an open resonator method under the conditions of a temperature of 23° C. and a frequency of 28 GHz. The measurement sample was formed by applying a resin varnish on the release film with a roll, then placing the film provided with a coating film in an oven, and drying at 110° C. for 4 minutes to form a B-stage adhesive layer (thickness of 50 μm). Next, the adhesive layer was heat-laminated at 150° C. such that its adhesive surfaces were in contact with each other to form a pre-curing adhesive film (thickness of 100 μm). This pre-curing adhesive film (thickness of 100 μm) was placed in an oven and heat-cured at 180° C. for 60 minutes to prepare a cured adhesive film (100 mm×100 mm). The release film was peeled from the cured adhesive film, and the relative permittivity and dielectric loss tangent of the adhesive layer were measured, and was evaluated according to the following evaluation criteria.

### [Evaluation Criteria of Relative Permittivity]

good: relative permittivity of less than 3.0
fair: relative permittivity of 3.0 or more and less than 3.5
poor: relative permittivity of 3.5 or more

### [Evaluation Criteria of Dielectric Loss Tangent]

good: dielectric loss tangent of less than 0.003
fair: dielectric loss tangent of 0.003 or more and less than 0.005
poor: dielectric loss tangent of 0.005 or more

The linear thermal expansion coefficient (CTE) (CTE at 20° C. to 140° C.) of the adhesive layer obtained by curing the resin varnish of Example 1 at 180° C. or 150° C. was obtained, and was evaluated according to the following evaluation criteria.

[Linear Thermal Expansion Coefficient (CTE) (ppm/K)]

The linear thermal expansion coefficient (CTE) was measured in a tensile mode with a thermomechanical analyzer (trade name: SII//SS7100, manufactured by Hitachi High-Tech Science Corporation) under conditions of a load of 50 mN and a temperature increase rate of 5° C./min in a range of 10° C. to 200° C., and a linear thermal expansion coefficient (ppm/K) was obtained based on the inclination in a range of 20° C. to 140° C. The measurement was performed in the widthwise direction (TD) of the resin film.

### [Evaluation Criteria of CTE (Ppm/K)]

excellent: CTE of less than 150
good: CTE of 150 or more and less than 200
fair: CTE of 200 or more and less than 500
poor: CTE of 500 or more

The resin varnish of Example 1 was used to produce a laminate having a cured adhesive by the following method.

### <Laminate Having Cured Adhesive>

The surface of a base film was subjected to a corona treatment.

The resin varnish produced as described above was applied to the surface of the base film, and the solvent was volatilized by drying the resultant in an oven at 130° C. for 4 minutes to form an adhesive layer (25 μm), whereby a base film having an adhesive (laminate having an adhesive) was obtained. The adhesive layer of the laminate having an adhesive was placed so as to be in contact with the glossy surface of an electrolytic copper foil, and the resultant was pressed with a vacuum press machine at 180° C. under a pressure (of 3 MPa), and 10 hPa for 3 minutes, and then subjected to after-curing at 180° C. for 1 hour to cure the adhesive layer, and thus, a laminate having a cured adhesive was obtained.

In the laminate having a cured adhesive of Example 1, the peeling force (adhesion) (N/cm) between the electrolytic copper foil and the base film was measured.

### [Peeling Force (N/Cm)]

The peeling force was measured by cutting the laminate having a cured adhesive to obtain a test piece having a width of 25 mm, and then measuring the peeling strength in peeling the electrolytic copper foil from the base film having an adhesive fixed to a support at a peeling rate of 0.3 m/min at a peeling angle of 1800 in accordance with JIS Z0237: 2009 (pressure-sensitive adhesive tape/pressure-sensitive adhesive sheet test method), and was evaluated according to the following criteria.

### [Evaluation Criteria of Peeling Force]

excellent: peeling force of 8 N/cm or more
good: peeling force of 7 N/cm or more and less than 8 N/cm
fair: peeling force of 6 N/cm or more and less than 7 N/cm
poor: peeling force of less than 6 N/cm

The respective evaluation results of the adhesive layer and the laminate having an adhesive layer of Example 1 are shown in Table 2.

### Examples 2 to 7

Adhesive layers and laminates having adhesive layers of Examples 2 to 7 were prepared in the same manner as in Example 1 except that the types and amounts to be blended of components contained in adhesive layers were changed in Example 1 as shown in Table 1.

The adhesive layers and the laminates having adhesive layers thus prepared were evaluated in the same manner as in Example 1.

The results are shown in Table 2.

### Comparative Examples 1 to 3

Adhesive layers and laminates having adhesive layers of Comparative Examples 1 to 3 were prepared in the same manner as in Example 1 except that the types and amounts to be blended of components contained in adhesive layers were changed in Example 1 as shown in Table 1.

The adhesive layers and the laminates having adhesive layers thus prepared were evaluated in the same manner as in Example 1.

The results are shown in Table 2.

TABLE 1

| | Component (parts by mass) | | | | | | | |
|---|---|---|---|---|---|---|---|---|
| | Maleimide Resin | | | | | | | |
| | (Bismaleimide Resin) | | | | | | | |
| | SLK-3000-T50 | SLK-6895-M90 | | | | | | |
| | (high molecular | (low molecular | Benzoxazine Resin | | Alkenyl Resin | Allyl Resin | Epoxy Resin | Silica |
| | weight) | weight) | ALP-d | CR-276 | BPN01S | APG-LC | HP-7200 | SO-C2 |
| Example 1 | 75 | | 5 | | 20 | | | 200 |
| Example 2 | 80 | | 5 | | 15 | | | 200 |
| Example 3 | 85 | | 5 | | 10 | | | 200 |
| Example 4 | 80 | | 10 | | 10 | | | 200 |
| Example 5 | 90 | | 5 | | 5 | | | 200 |
| Example 6 | 90 | | | 5 | 5 | | | 200 |
| Example 7 | 75 | | 5 | | 15 | | 5 | 200 |
| Comparative | | 75 | 5 | | | 20 | | 200 |
| Example 1 | | | | | | | | |
| Comparative | 75 | | 5 | | | 20 | | 200 |
| Example 2 | | | | | | | | |
| Comparative | | 90 | 5 | | 5 | | | 200 |
| Example 3 | | | | | | | | |

TABLE 2

| | | Dielectric | CTE in | CTE in | |
|---|---|---|---|---|---|
| | Relative | Loss | curing at | curing at | Peeling |
| | Permittivity | Tangent | 180° C. | 150° C. | Force |
| | (28 GHz) | (28 GHz) | (ppm/K) | (ppm/K) | (N/cm) |
| Example 1 | good | fair | good | fair | good |
| Example 2 | good | fair | excellent | good | excellent |
| Example 3 | good | good | excellent | excellent | excellent |
| Example 4 | good | good | excellent | excellent | excellent |
| Example 5 | good | good | excellent | excellent | excellent |
| Example 6 | good | good | excellent | excellent | excellent |
| Example 7 | good | fair | good | fair | good |
| Comparative | good | fair | good | fair | poor |
| Example 1 | | | | | |
| Comparative | good | fair | fair | poor | good |
| Example 2 | | | | | |
| Comparative | good | good | fair | fair | poor |
| Example 3 | | | | | |

As shown in Examples, the adhesive composition of the present invention exhibits 5G compatible good electrical properties (low-dielectric properties), and forms a good film (adhesive layer) through low-temperature curing, and the thus formed adhesive layer exhibits excellent adhesiveness, and a small CTE.

### INDUSTRIAL APPLICABILITY

The laminate having an adhesive layer composed of the adhesive composition of the present invention can be suitably used in the production of FPC-related products for electronic devices, including smartphones, mobile phones, optical modules, digital cameras, game machines, laptop computers and medical instruments.

1. An adhesive composition comprising a resin composition comprising a maleimide resin (A) having a molecular weight of 1,000 or more, a benzoxazine resin (B), and an alkenyl resin (C) having a 1-alkenyl group,
wherein a mixing ratio between the benzoxazine resin (B) and the alkenyl resin (C) in the resin composition is 1:10 to 10:1.

2. The adhesive composition according to claim 1, wherein the number of carbon atoms in the 1-alkenyl group is 5 or less.

3. The adhesive composition according to claim 2, wherein the 1-alkenyl group is a 1-propenyl group.

4. The adhesive composition according to claim 1, wherein the benzoxazine resin (B) has a molecular weight of 1,000 or less.

5. The adhesive composition according to claim 1, wherein the benzoxazine resin (B) has a softening point of 100° C. or less.

6. The adhesive composition according to claim 1, wherein the alkenyl resin (C) has a molecular weight of 1,000 or less.

7. The adhesive composition according to claim 1, wherein the alkenyl resin (C) has a softening point of 100° C. or less.

8. The adhesive composition according to claim 1, wherein, as a mixing ratio among the maleimide resin (A), the benzoxazine resin (B), and the alkenyl resin (C), 62.5 to 99.8 parts by mass of the maleimide resin (A), 0.1 to 25 parts by mass of the benzoxazine resin (B), and 0.1 to 12.5 parts by mass of the alkenyl resin (C) are mixed based on 100 parts by mass of the resin composition.

9. The adhesive composition according to claim 1, wherein the mixing ratio between the benzoxazine resin (B) and the alkenyl resin (C) in the resin composition is 1:3 to 3:1.

10. The adhesive composition according to claim 1, wherein when the resin composition contains an epoxy resin, a content of the epoxy resin is less than 5 parts by mass based on 100 parts by mass of the resin composition.

11. The adhesive composition according to claim 10, wherein when the resin composition contains the epoxy resin, the content of the epoxy resin is less than 3 parts by mass based on 100 parts by mass of the resin composition.

12. The adhesive composition according to claim 1, wherein the resin composition contains no epoxy resin.

13. The adhesive composition according to claim 1, further comprising a filler in addition to the resin composition.

14. An adhesive layer obtained by curing the adhesive composition according to claim 1.

15. The adhesive layer according to claim 14, wherein the adhesive layer has relative permittivity measured at 28 GHz of 3.5 or less, and a dielectric loss tangent of 0.005 or less.

16. A laminate, comprising:
a base film; and
the adhesive layer according to claim 14.

17. A coverlay film having an adhesive layer, comprising the laminate according to claim 16.

18. A copper-clad laminate comprising the laminate according to claim 16.

19. A printed wiring board comprising the laminate according to claim 16.
